(19) United States
(12) Patent Application Publication
(10) Pub. No.: US 2008/0290364 A1
(43) Pub. Date: Nov. 27, 2008

(54) Semiconductor light-emitting element and a producing method thereof

(75) Inventors: Masao Kamiya, Aichi-ken (JP); Yukitaka Hasegawa, Aichi-ken (JP); Shingo Totani, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/153,811

(22) Filed: May 23, 2008

(30) Foreign Application Priority Data
May 24, 2007 (JP) P. 2007-137628

(51) Int. Cl. H01L 33/00

(52) U.S. Cl. 257/99; 438/46; 257/E33.064

(57) ABSTRACT

A semiconductor light-emitting element 100 is formed including a buffer layer 102, a n-type GaN layer 103, a light-emitting layer 104 and a p-type layer 105 laminated in this order on a sapphire substrate and has a light transmitting electrode 106 made of a needle crystal of ITO.

### BACKGROUND OF THE INVENTION

1. Field of the Invention

The present invention relates to a semiconductor light-emitting element formed by laminating a III group nitride compound semiconductor. The invention relates particularly to a semiconductor light-emitting element on a surface of which a thin film made of a needle crystal of indium tin oxide (ITO) is formed.

2. Description of the Related Art

At present, it is general that, in a III group nitride compound semiconductor element, with a nonconductive sapphire substrate, both of an n-electrode and a p-electrode are formed on a side of a semiconductor element layer. Here, in a so-called face-up type III group nitride compound semiconductor element, by use of a thin film light transmitting electrode made of, for instance, alloyed gold (Au) and cobalt (Co) on a p-type layer surface, light is extracted from a side where the electrode is formed. However, the Au/Co thin film light transmitting electrode has the light transmittance of substantially 60%; accordingly, the light extraction efficiency is not said sufficient.

On the other hand, as a light transmitting electrode of a III group nitride compound semiconductor light-emitting element, indium tin oxide (ITO) is proposed to use (patent literature 1). However, even when the ITO is used as a light-transmitting electrode, due to the total reflection on an ITO surface, the light extraction efficiency is not yet said sufficient. Furthermore, the light extraction from a portion other than the p-electrode of the III group nitride compound semiconductor light-emitting element, for instance, a periphery of the n-electrode, a side surface and a substrate side where the III group nitride compound semiconductor is not formed is neither said sufficient due to the total reflection.

Still furthermore, in patent literature 2, a method where fine needle particles of ITO are coated and heated to form an ITO film is disclosed.

Patent literature 1: Japanese Patent No. 3394488

Patent literature 2: JP-A No. 2006-212584

As to an ITO film, a method of improving the light extraction efficiency has not yet discovered. Accordingly, the invention intends to provide, in order to improve the light extraction efficiency, a III group nitride compound semiconductor light-emitting element on a surface of which a thin film made of a needle crystal of ITO formed in needle during the film formation is formed.

### SUMMARY OF THE INVENTION

In order to overcome the problems, according to the first aspect of the invention, in a semiconductor light-emitting element formed by laminating a III group nitride compound semiconductor on a substrate, on a surface of the semiconductor light-emitting element, a thin film made of a needle crystal of ITO formed during the film formation is formed.

Furthermore, according to the second aspect of invention, the thin film is an electrode of the semiconductor light-emitting element. According to the third aspect of the invention, the thin film is formed on a side surface of the semiconductor light-emitting element. Furthermore, according to the fourth aspect of the invention, the thin film is formed on a side where the III group nitride compound semiconductor is not laminated of the substrate.

According to the fifth aspect of the invention, in a producing method of a semiconductor light-emitting element formed by laminating a III group nitride compound semiconductor, on a surface of the semiconductor light-emitting element, a thin film made of a needle crystal of ITO is formed under a vacuum of 1.0×10⁻¹ Pa or less by use of a vacuum deposition method, an ion implantation method or a sputtering method.

As will be shown below, the present inventors found that when a thin film made of a needle crystal of ITO is formed on a surface of a semiconductor light-emitting element, the light extraction efficiency is improved.

### BRIEF DESCRIPTION OF THE DRAWINGS

FIG. 1 shows a surface SEM photograph of an ITO film involving example 1 of the invention;

FIG. 2 is a surface SEM photograph of an ITO film involving comparative example 1;

FIG. 3 is a sectional view showing a configuration of a semiconductor light-emitting element 100 involving example 2 of the invention;

FIG. 4 is a sectional view showing a configuration of a semiconductor light-emitting element 200 involving example 3 of the invention;

FIG. 5 is a sectional view showing a configuration of a semiconductor light-emitting element 300 involving example 4 of the invention; and

FIG. 6 is a sectional view showing a configuration of a semiconductor light-emitting element 400 involving example 5 of the invention.

### DESCRIPTION OF THE PREFERRED EMBODIMENTS

The needle crystal of ITO preferably has a size of 200 nm or less. When the size is more than 200 nm, the light extraction efficiency is improved less.

An ITO film may be formed as a light-transmitting electrode of a semiconductor light-emitting element. When an n-type layer, a light-emitting layer and a p-type layer of a III group nitride compound semiconductor are laminated on a substrate and a thin film made of a needle crystal of ITO is formed on the p-type layer to form an electrode, a semiconductor light-emitting element excellent in the light extraction efficiency is obtained. Furthermore, also when a thin film made of a needle crystal of ITO is formed on a side surface of the semiconductor light-emitting element or on a side where the III group nitride compound semiconductor is not laminated of the substrate, a semiconductor light-emitting element excellent in the light extraction efficiency is obtained.

The ITO film is formed by use of a vacuum deposition method, an ion implantation method or a sputtering method. At this time, the vacuum is preferably set at 1.0×10⁻¹ Pa or less. When the ITO film is formed outside of the range, an ITO film excellent in the light extraction efficiency and made of needle crystal is not obtained. Furthermore, after the ITO film is formed, the ITO film is preferably heated at 600° C. or more in an inert gas atmosphere.

When an ITO film is formed as a light-transmitting electrode, a pad electrode is preferably for wire bonding. A pad electrode is preferably formed of a thick film of gold (Au). A thickness thereof is arbitrarily set in the range of 0.5 to 3 μm. In the case of the pad electrode being mainly formed of Au, when nickel (Ni), titanium (Ti), chromium (Cr) or aluminum (Al) is formed between the light transmitting electrode made of ITO, the adhesion between the pad electrode and the light transmitting electrode made of ITO is enhanced. In particular, when nickel (Ni) is used, the adhesion is more enhanced.

The III group nitride compound semiconductor light-emitting element involving the invention may have an arbitrary configuration except for restrictions involving a main configuration of the invention. Furthermore, as a producing method of the III group nitride compound semiconductor light-emitting element involving the invention, an arbitrary producing method may be used.

Specifically, as a substrate on which a crystal is grown, sapphire, spinel, Si, SiC, ZnO, MgO or III group nitride compound single crystals may be used. As a method of crystal growth of a III group nitride compound semiconductor layer, a molecular beam epitaxy (MBE) method, a metal-organic vapor phase epitaxy method (MOVPE), a hydride vapor phase epitaxy method (HVPE) and a liquid phase growth method are effective.

When a light-emitting layer is formed into a multiple quantum well structure, a well layer made of a III group nitride compound semiconductor, AlₓGa_{y}In_{1-x-y}N (0≦x<1, 0<y≦1), containing at least indium (In) is preferably contained. A light-emitting layer is configured of, for instance; a well layer made of a doped or undoped Ga_{y}In_{1-y}N (0<y≦1) and a barrier layer made of a III group nitride compound semiconductor, AlGaInN, that is larger in the band gap than the well layer and has an arbitrary composition. As a preferable example, a well layer made of undoped Ga_{y}In_{1-y}N (0<y≦1) and a barrier layer made of undoped GaN are cited.

A III group nitride semiconductor layer such as an electrode-forming layer may be formed of a III group nitride compound semiconductor made of a binary, ternary or quaternary semiconductor at least expressed by AlₓGa_{y}In_{1-x-y}N (0≦x≦1, 0≦y≦1, 0≦x+y≦1). Furthermore, the III group elements may be partially substituted by boron (B) or thallium (TI) and nitrogen (N) may be partially substituted by phosphorus (P), arsenic (As), antimony (Sb) or bismuth (Bi).

Still furthermore, when the semiconductor is used to form a n- or p-type III group nitride compound semiconductor layer, examples of n-type impurities added include Si, Ge, Se, Te and C and examples of p-type impurities include Zn, Mg, Be, Ca, Sr and Ba.

The n-type III group nitride compound semiconductor layer is formed into a multi-layer structure such as a n-type contact layer and a superlattice strain relief layer of GaN/GaInN, and the p-type III group nitride compound semiconductor layer is formed into a multi-layer structure such as a p-type contact layer and a superlattice clad layer of AlGaN/GaInN.

According to the means of the invention mentioned above, the problems are effectively or reasonably overcome.

### EXAMPLE 1

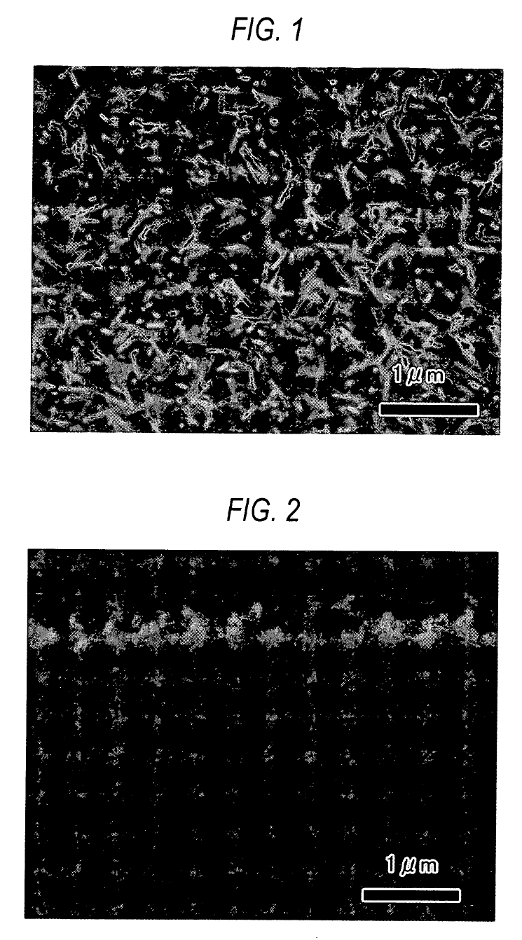

In FIG. 1, a surface SEM photograph of an ITO film involving a first example of the invention is shown. In the beginning, in order to show a formation state of a needle crystal of ITO in a semiconductor light-emitting element of the invention, an experiment shown below was carried out. With a mixture of tin oxide and indium oxide (tin oxide: 5%) as a target, by use of a vacuum deposition method, on p-type GaN, ITO having a film thickness of 300 nm was formed. At this time, when the vacuum while an ITO film was deposited was set at 2.5×10⁻³ Pa, an ITO film shown in FIG. 1 was formed. It is found that a thin film made of needle crystals having a length of 500 nm and a size of 100 nm and excellent in the light extraction efficiency is formed. Here, in order to stabilize the vacuum at the time of deposition, after a high vacuum (1×10⁻⁴ Pa or less) is once attained, a predetermined amount of oxygen is introduced to control to a predetermined vacuum. In this case, the vacuum at the time of deposition is oxygen pressure.

### COMPARATIVE EXAMPLE 1

On the other hand, a surface SEM photograph of an ITO film formed when the vacuum at the time of deposition of the ITO film is set at 5.0×10⁻¹ Pa is shown in FIG. 2. In this case, excellent needle crystal is not obtained and the light extraction efficiency is not improved.

### EXAMPLE 2

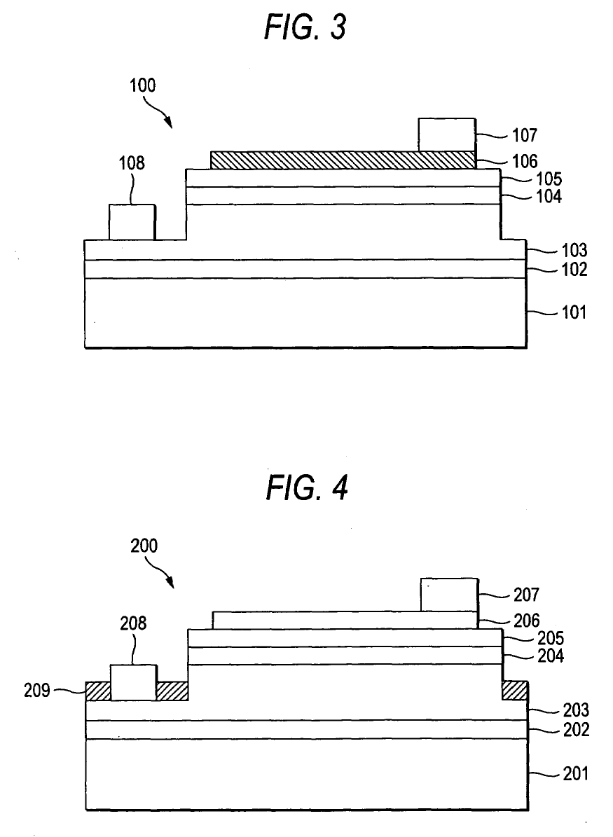

In FIG. 3, a schematic sectional view of a semiconductor light-emitting element 100 involving a second example of the invention is shown. In the semiconductor light-emitting element 100, as shown in FIG. 3, on a sapphire substrate 101 having a thickness of substantially 400 μm, a buffer layer 102 made of aluminum nitride (AlN) and having a film thickness of substantially 15 nm was deposited, and, further thereon, a n-type layer 103, a light-emitting layer 104 and a p-type layer 105, which are made of a III group nitride compound semiconductor, are formed.

Furthermore, on the p-type layer 105, a light transmitting p-electrode 106 made of a needle crystal of ITO is formed and, on the n-type layer 103, a n electrode 108 is formed.

A p pad electrode 107 is configured by sequentially laminating a first layer 121 made of Ni having a film thickness of substantially 30 nm, a second layer 122 made of Au having a film thickness of substantially 1.5 μm and a third layer 123 made of Al having a film thickness of substantially 10 nm on a light transmitting p-electrode 110.

An n-electrode 108 having a multi-layer structure is configured by laminating a first layer 141 made of vanadium (V) having a film thickness of substantially 18 nm and a second layer 142 made of Al having a film thickness of substantially 100 nm from above a partially exposed portion of the n-type contact layer 104.

In a semiconductor light-emitting element, on a sapphire substrate, a buffer layer 102, a n-type layer 103, a light-emitting layer 104 and a p-type layer 105 were sequentially epitaxially grown, followed by etching to form a n-electrode 108, further followed by forming an electrode as shown below.

With a mixture of tin oxide and indium oxide (tin oxide: 5%) as a target, by means of the vacuum deposition method, a light transmitting p electrode 106 made of a needle crystal of ITO and having a film thickness of 300 nm was formed on the p-type layer 105 under the vacuum of 2.5×10⁻³ Pa. Thereafter, a resist was formed by use of ordinary photolithography, followed by wet etching the ITO film to patternize the ITO film.

In the next place, a mask where a region where a thick film p-electrode 107 is to be formed is a window is formed of a photoresist is formed, followed by sequentially forming a first layer made of Ni having a film thickness of substantially 30 nm, a second layer made of Au having film thickness of substantially 1.5 μm and a third layer made of Al having a film thickness of substantially 10 nm on the light transmitting p-electrode 106, further followed by removing the photoresist.

Utterly similarly, after a mask where a region where a n-electrode 108 is to be formed is a window is formed of a photoresist is formed, a first layer made of V having a film thickness of substantially 18 nm and a second layer made of Al having a film thickness of substantially 100 nm were formed on an exposed region of the n-type layer 103, followed by removing the photoresist.

Then, the light transmitting p-electrode (ITO) 106, the thick film p-electrode 107 and the n-electrode 108 were heated. In the last, a protective film made of SiO₂ was formed. A protective film 130 may be formed of SiNₓ in place of SiO₂.

### COMPARATIVE EXAMPLE 2

In the example, when the vacuum (oxygen pressure) was set at 5.0×10⁻¹ Pa at the time of depositing the light transmitting p-electrode (ITO) 106 and a similar semiconductor light-emitting element was prepared, ITO did not form needle crystal and the emission characteristics were 14.5 mW in the total radiant flux. On the other hand, the total radiant flux of the semiconductor light-emitting element of the invention was 15.5 mW in the total radiant flux, that is, the total radiant flux was improved.

### EXAMPLE 3

In FIG. 4, a schematic sectional view of a semiconductor light-emitting element 200 involving a third example of the invention is shown. In the semiconductor light-emitting element 200, as shown in FIG. 4, on a p-type layer 205, a light transmitting p-electrode 206 made of a needle crystal of ITO was disposed, and, on a n-type layer 203, a n pad electrode 208 made of V/Al was disposed. Furthermore, on an exposed portion that is not covered by the n pad electrode 208 of the n-type layer 203, a thin film 209 made of a needle crystal of ITO was disposed. Owing to the disposition of a light transmitting thin film made of a needle crystal of ITO on the n-type layer, the light extraction efficiency was further improved.

As a modification example of example 3, a light transmitting n-electrode made of a needle crystal of ITO may be disposed on the n-type layer, followed by disposing, further thereon, a n pad electrode.

### EXAMPLE 4

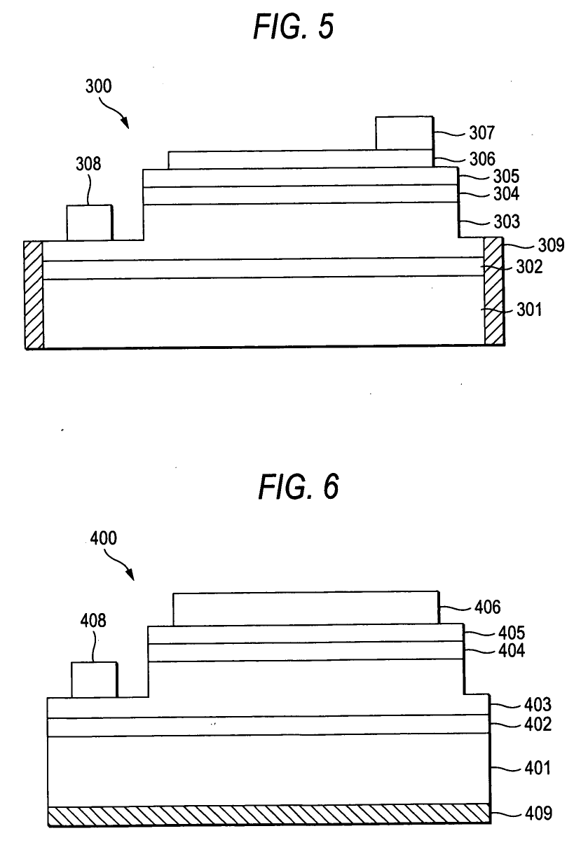

In FIG. 5, a schematic sectional view of a semiconductor light-emitting element 300 involving a fourth example of the invention is shown. In the semiconductor light-emitting element 300, as shown in FIG. 5, owing to the disposition of a light transmitting thin film 309 made of a needle crystal of ITO on a side surface of a p semiconductor light-emitting element, the light extraction efficiency from a side surface of the semiconductor light-emitting element was improved.

In examples 3 and 4, as a light transmitting p-electrode, an existing light transmitting electrode made of metal such as Co/Au and Ni/Au may be used.

### EXAMPLE 5

In FIG. 6, a schematic sectional view of a semiconductor light-emitting element 400 involving a fifth embodiment of the invention is shown. The semiconductor light-emitting element 400, as shown in FIG. 6, is configured in a so-called flip-chip type where light is extracted from a side where a III group nitride compound semiconductor is not laminated of a semiconductor light-emitting element. Here, when a p electrode 406 made of Rh/Au was disposed on a p-type layer 405 and a light transmitting thin film 409 made of a needle crystal of ITO was disposed on a side where the III group nitride compound semiconductor was not laminated, the light extraction efficiency from the semiconductor light-emitting element was enhanced.

In examples 3, 4 and 5, the light extraction efficiency from a periphery of a n-electrode of the semiconductor light-emitting element, side surfaces thereof and a surface on a side of a substrate where the III group nitride compound semiconductor was not laminated was improved.

What is claimed is:

1. A semiconductor light-emitting element formed by laminating a III group nitride compound semiconductor on a substrate, wherein, on a surface of the semiconductor light-emitting element, a thin film made of a needle crystal of indium tin oxide (ITO) formed during film formation is formed.

2. The semiconductor light-emitting element of claim 1, wherein the thin film is an-electrode of the semiconductor light-emitting element.

3. The semiconductor light-emitting element of claim 1, wherein the thin film is formed on a side surface of the semiconductor light-emitting element.

4. The semiconductor light-emitting element of claim 1, wherein the thin film is formed on a side where the III group nitride compound semiconductor is not laminated of the substrate.

5. A producing method of a semiconductor light-emitting element formed by laminating a III group nitride compound semiconductor, wherein, on a surface of the semiconductor light-emitting element, a thin film made of a needle-like crystal of indium tin oxide (ITO) is formed under a vacuum of 1.0×10⁻¹ Pa or less by use of a vacuum deposition method, an ion implantation method or a sputtering method.
